(19) United States
(12) Patent Application Publication
(10) Pub. No.: US 2006/0109613 A1
(43) Pub. Date: May 25, 2006

(54) WEBCAM AND HOLDER ARRANGEMENT

(75) Inventor: Mei-Chi Chen, TAIPEI (TW)

Correspondence Address: CHEN-SOURCE INC., P.O. BOX 108-00403, TAIPEI, TW

(73) Assignee: CHEN-SOURCE INC., Taipei Hsien (TW)

(21) Appl. No.: 10/904,753

(22) Filed: Nov. 25, 2004

(51) Int. Cl. H05K 5/00

(52) U.S. Cl. 361/679

(57) ABSTRACT

A webcam and holder arrangement is disclosed to include a holder base provided with a cover, a winding mechanism provided inside the holder base, and a webcam, which has a cable inserted through the holder base and fastened to the winding mechanism and terminating at an electric connector connectable to a computer such that the directly place the webcam on the cover of the holder base or pulled with the cable out of the holder base and hung with the cable on a LCD with the focusing lens thereof aimed at the user.

### BACKGROUND OF THE INVENTION

1. Field of the Invention

The present invention relates generally to a webcam and more particularly, to a webcam and holder arrangement, which allows the user to hang the webcam on the front side of a computer monitor to photograph the image of the user sitting in front of the computer monitor.

2. Description of the Related Art

Following the digitalized video era, video dissemination allows video data to be rapidly sent to every corner around the world. The maturity of the development of broadband network facilitates application of videophone. Through the Internet and external peripheral apparatus, image, sound and data can be transmitted together for education on air, multivideo group conference in a multinational company, remote on-line real-time communication among people, etc. A video communication must use a webcam to achieve image transmission. FIG. 6 shows a conventional webcam for this purpose. As illustrated, the webcam comprises a holder base A, two uprights A1, two transverse pivots A2, and a webcam body B supported between the uprights A1. The webcam body B has two coupling holes B2 disposed at two sides and respectively pivotally coupled to the respective pivots A2 at the uprights A1. When in use, the user can turn the webcam body B on the pivots A2 to aim the focusing lens B1 at the user's face. This structure of webcam requires much tabletop space. When put on the top of the worktable, it may be forced to displace or to fall to the tabletop by an external force or vibration accidentally. Falling of the webcam to the tabletop may cause damage to the webcam's focusing lens or internal circuit. Further, because the webcam is to be set on the top of the worktable but not attached to the monitor (LCD), the user may have to frequently adjust the position and angle of the webcam during a video meeting. FIGS. 7 and 8 show another prior art webcam design. According to this design, the webcam holder comprises a holder base D and an adjustable table C for holding a webcam B. The adjustable table C comprises two parallel sliding grooves C1 symmetrically bilaterally provided at the bottom, and a bottom lug C2 equally spaced between the sliding grooves C1 near the front side. The holder base D comprises a flat plate D1 inserted into the adjustable table C, two rails D11 disposed at two sides of the flat plate D1 and respectively coupled to the sliding grooves C1, and a top lug D2 equally spaced between the rails D11 and connected to the bottom lug C2 of the adjustable table C by a spring member E. The holder base D further comprises a swinging frame D3 for mounting. The swinging frame D3 can be set in parallel to the flat plate D1 to support the flat plate D1 steadily on a flat surface. Alternatively, the swinging frame D3 can be turned outwards from the flat plate D1 for securing the webcam holder to a computer monitor (LCD). This prior art design is still not satisfactory in function. When fastening the webcam holder to a computer monitor (LCD), the holder base D may damage the surface structure of the computer monitor (LCD) accidentally. After installation of the webcam holder in a computer monitor (LCD), the webcam body B is held to the slightly backwardly tilting front side of the computer monitor (LCD) in a slightly backwardly tilting position at a certain height where the user is difficult to adjust the optimum photographing angle of the focusing lens B1 of the webcam body B1. Further, it is complicated to mount the webcam holder on a computer monitor (LCD) or dismount the webcam holder from the computer monitor (LCD).

Therefore, it is desirable to provide a webcam and holder arrangement that eliminates the aforesaid drawbacks.

### SUMMARY OF THE INVENTION

The present invention has been accomplished under the circumstances in view. It is one object of the present invention to provide a webcam and holder arrangement, which enables the user to hung the webcam on the front side of a LCD and aimed at the user sitting in front of the LCD. It is another object of the present invention to provide a webcam and holder arrangement, which allows the user to conveniently adjust webcam to the optimum photographing position. To achieve these and other objects of the present invention, the webcam and holder arrangement comprises a webcam, which has a cable terminating at an electric connector connectable to a computer, and a holder base adapted to hold the webcam, wherein the holder base comprises a winding mechanism provided on the inside and fastened to the cable to wind up the cable for enabling the user to pull the webcam with the cable to a distance away from the holder base, and a cover adapted to support the webcam.

### BRIEF DESCRIPTION OF THE DRAWING

FIG. 1 is an exploded view of the preferred embodiment of the present invention.

FIG. 2 is an elevational assembly view of the preferred embodiment of the present invention.

FIG. 3 is a sectional elevation of the present invention, showing the webcam placed on the top of the cover.

FIG. 4 shows one application example of the preferred embodiment of the present invention.

FIG. 5 shows another application example of the preferred embodiment of the present invention.

FIG. 6 is an elevational view of a webcam according to the prior art.

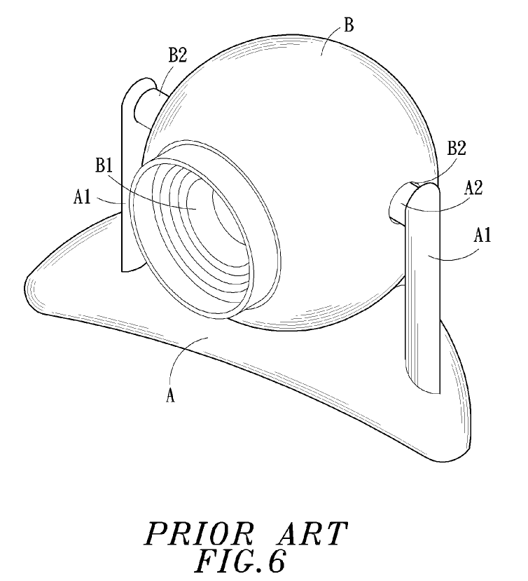

FIG. 7 is an exploded view of webcam holder according to the prior art.

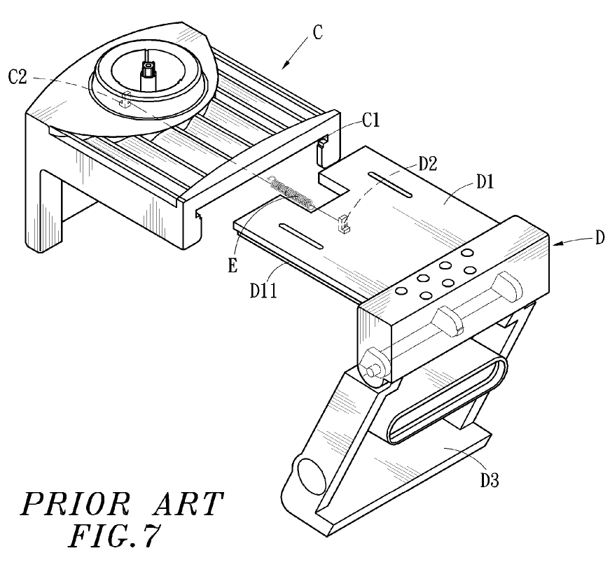

FIG. 8 illustrates a webcam mounted on the webcam holder shown in FIG. 7.

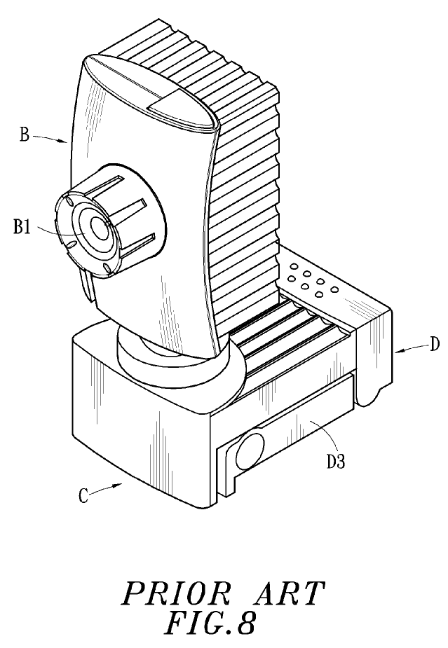

### BRIEF DESCRIPTION OF THE INVENTION

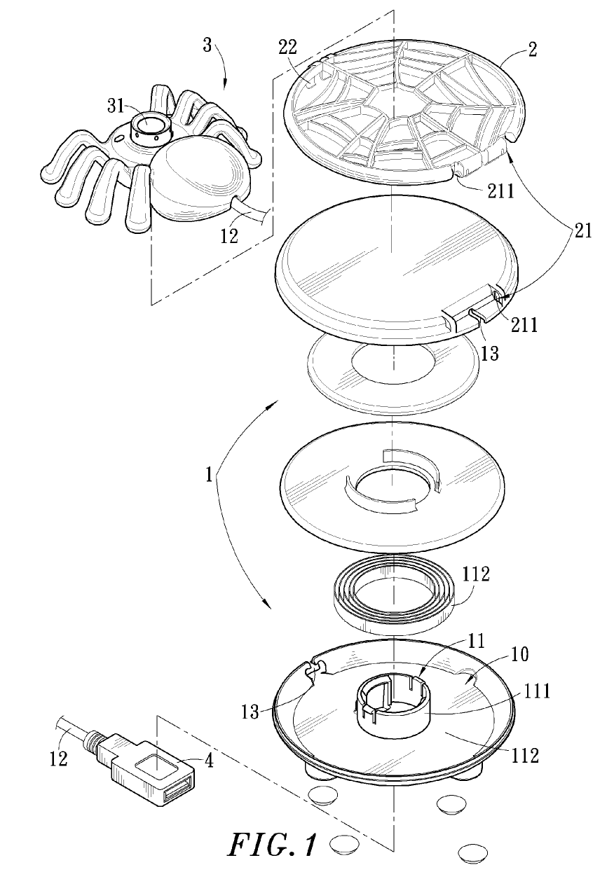

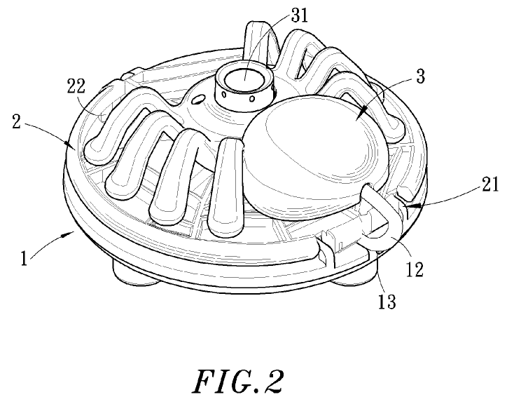

Referring to FIGS. 1-3, a webcam and holder arrangement in accordance with the present invention is shown comprising a holder base 1, a cover 2, a webcam 3, a cable 12, and an electric connector 4.

The holder base 1 comprises an inside chamber 10, a winding mechanism 111 provided in the inside chamber 10, and two cable holes 13. The winding mechanism 111 comprises an upright shaft 111 vertically disposed at the center in the inside chamber 10, and a spiral spring 112 mounted on the upright shaft 111.

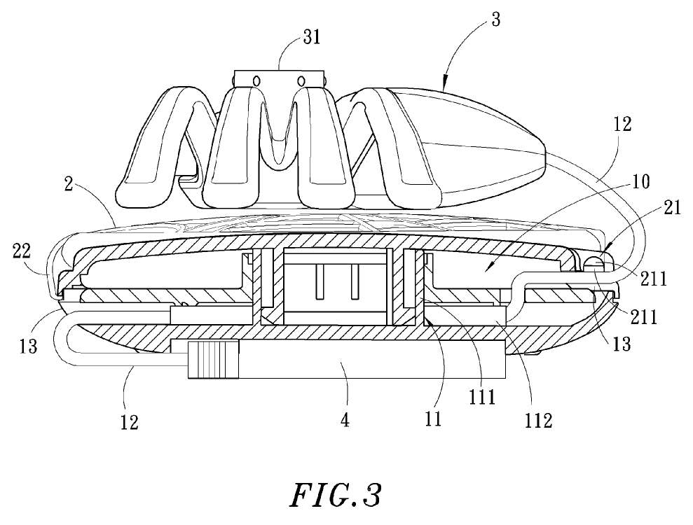

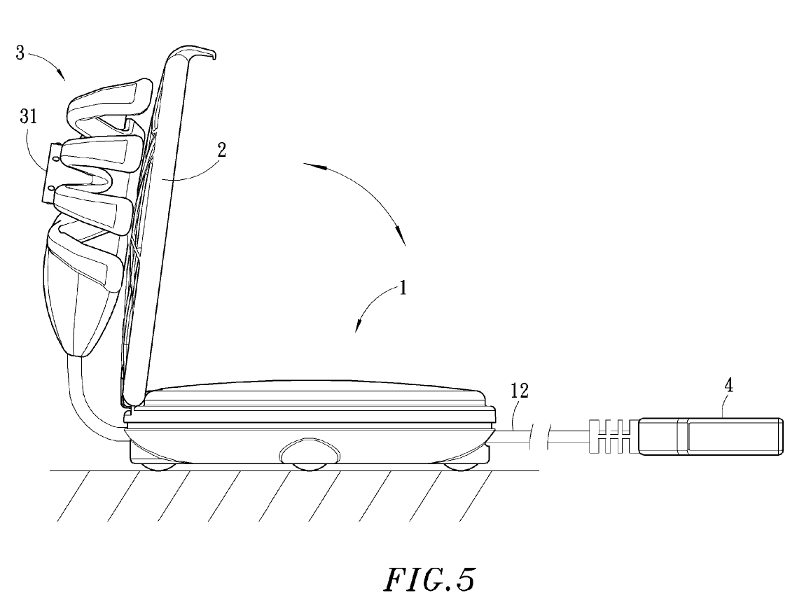

The cover 2 is connected to the holder base 1 through a joint (for example, hinge) 21. According to the present preferred embodiment, the joint 21 is comprised of two joint members 211 respectively provided at the cover 2 and the holder base 1. The two joint members 211 are pivotally connected together such that the cover 2 can be turned relative to the holder base 1 between a close position (see FIG. 3) and an open position (see FIG. 5).

The cable 12 is fastened to the spiral spring 112 and wound with the spiral spring 112 round the upright shaft 111, having two distal ends respectively extended out of the cable holes 13 of the holder base 1 and respectively connected to the webcam 3 and the electric connector 4. The webcam 3 has a focusing lens 31 for picking up the image of an object, field, etc. The electric connector 4 is connectable to a computer for enabling the computer to control the operation of the webcam 3. Because the cable 12 is fastened to the spiral spring 112 and wound with the spiral spring 112 round the upright shaft 111, the webcam 3 can be pulled with the cable 12 to a certain distance away from the holder base 1. When released the pulling force from the webcam 3, the spiral spring 112 automatically pulls the cable 12 back to the inside of the holder base 1. Further, the cover 2 has a retainer 22, which is forced into engagement with a part of the holder base 1 to hold the cover 2 in position after the cover 2 has been closed on the holder base 1. After the cover 2 has been closed on the holder base 1, the webcam 3 can be placed on the top side of the cover 2 and detachably secured thereto by a hook joint, hook and loop materials, or any of a variety of fastening devices (see FIG. 3).

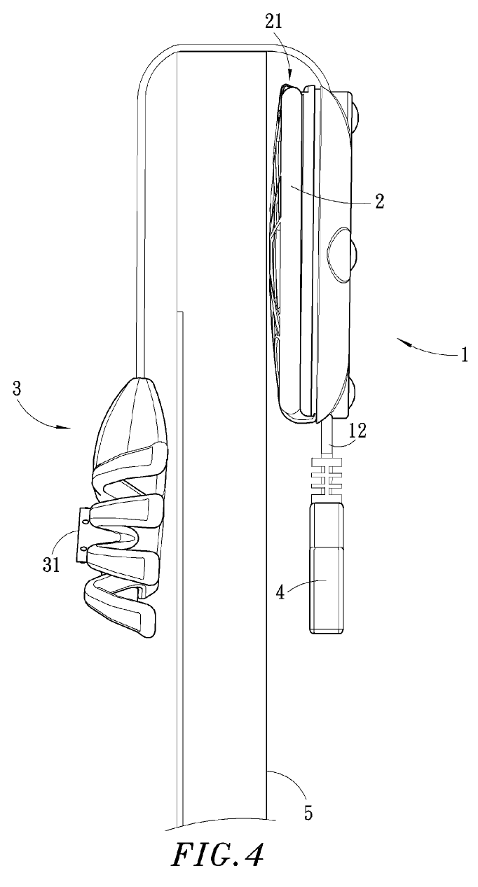

FIG. 4 shows one application example of the present invention. As illustrated, the holder base 1 and the cover 2 are suspending at the back side of a computer monitor (LCD) 5, the webcam 3 is pulled with the cable 12 out of the holder base 1 over the top side of the computer monitor (LCD) 5 and suspending at the front side of the computer monitor (LCD) 5 with the focusing lens 31 aimed at the user sitting in front of the computer monitor (LCD) 5.

FIG. 5 shows another application example of the present invention. As illustrated, the holder base 1 is placed on a flat bearing surface (the top wall of a CRT monitor or the top surface of a desk), the cover 2 is maintained in the opened status holding the webcam 3 in a substantially vertical position with the focusing lens 31 aimed at the user sitting in front of the flat bearing surface.

As indicated above, the video camera can be hung on the top of any of a variety of computer monitors (LCDs) with the holder base 1 and the webcam 3 respectively suspending at the back and front sides of the computer monitor (LCD) 5 and maintained in balance. Further, the user can pull the webcam 3 with the cable 12 away from the holder base 1 to a certain distance, enabling the focusing lens 31 of the webcam 3 to be set in the optimum photographing position.

Although a particular embodiment of the invention has been described in detail for purposes of illustration, various modifications and enhancements may be made without departing from the spirit and scope of the invention. Accordingly, the invention is not to be limited except as by the appended claims.

What is claimed is:

1. A webcam and holder arrangement comprising a webcam, said webcam having a cable terminating at an electric connector connectable to a computer, and a holder base adapted to hold said webcam, wherein said holder base comprises a winding mechanism provided on the inside and fastened to said cable to wind up said cable for enabling the user to pull said webcam and said cable to a distance away from said holder base, and a cover adapted to support said webcam.

2. The webcam and holder arrangement as claimed in claim 1, wherein said holder base has two cable holes disposed at two opposite sides for the passing of said cable.

3. The webcam and holder arrangement as claimed in claim 1, wherein said winding mechanism comprises an upright shaft, and a spiral spring wound round said upright shaft and fastened to said cable.

4. The webcam and holder arrangement as claimed in claim 1, wherein said cover is hinged to said holder base by joint means.
